(19) United States
(12) Patent Application Publication
(10) Pub. No.: US 2018/0291269 A1
(43) Pub. Date: Oct. 11, 2018

(54) ETCHANT

(71) Applicant: Nagase ChemteX Corporation, Osaka (JP)

(72) Inventor: Satoru YOSHIZAKI, Hyogo (JP)

(21) Appl. No.: 15/940,354

(22) Filed: Mar. 29, 2018

(30) Foreign Application Priority Data
Mar. 31, 2017 (JP) 2017-071311

(51) Int. Cl. C09K 13/06

(52) U.S. Cl. CPC C09K 13/06; H01L 21/32134

(57) ABSTRACT

The present invention aims to provide etchants suitable for etching indium oxide-based films in which precipitation of oxalic acid is reduced even when moisture is evaporated and which provide excellent residue removal not only on organic films and SiN but also on glass. Also, the present invention aims to provide etchants that have a high solubility of indium to reduce precipitation of a salt of oxalic acid and indium, and therefore can be used for a long period of time. The present invention also aims to provide etchants that maintain a high etching rate. Included is an etchant for etching an indium oxide-based film, the etchant containing: (A) oxalic acid; (B) a primary amine having two or more hydroxy groups and/or a polyhydric alcohol; and (C) water.

### TECHNICAL FIELD

The present invention relates to etchants for etching indium oxide-based films.

### BACKGROUND ART

Display devices such as liquid crystal displays (LCDs) and electroluminescent (EL) displays include transparent conductive films as pixel display electrodes, for example. Indium oxide-based transparent conductive films, e.g. indium tin oxide (ITO) films, have been widely used as these transparent conductive films. For example, an ITO film may be formed on a substrate (e.g. glass) by a deposition process such as sputtering. Then, the ITO film may be etched using, for example, a resist mask to form an electrode pattern on the substrate. Such etching processes include wet and dry processes. Wet processes employ etchants.

Processes for wet etching polycrystalline ITO films typically use strong acids such as hydrochloric acid which can cause corrosion of components such as aluminum interconnects during etching and which also allow etching to occur preferentially at the grain boundaries in the ITO films, thereby making it difficult to pattern such materials with high machining accuracy. In this context, a technique has recently been developed which uses an amorphous ITO film as a transparent conductive film, and a weak acid, in particular an aqueous oxalic acid solution, to etch the film. This technique, however, has a problem in that etching residues remain on the substrate. Another problem is that when a surfactant such as dodecylbenzenesulfonic acid is added to the etchant to solve the above problem, significant foaming of the etchant can occur although the formation of etching residues is reduced. Such significant foaming may push up the substrate, and the presence of bubbles on the substrate can inhibit etchant contact, thereby hindering etching. In these cases, accurate etching cannot be accomplished, possibly resulting in defects in interconnection patterns.

Meanwhile, especially in the field of LCDs, an undercoat film such as a silicon nitride (SiN) film or an organic film is formed on a glass substrate, and then an amorphous ITO film is formed on the undercoat film. Such a SiN film is used, for example, to prevent contamination of metallic impurities from the glass substrate, while such an organic film is used, for example, to flatten the aperture region and improve the aperture ratio. However, when an ITO film formed on such an undercoat film is etched, etching residues can easily occur. Therefore, with conventional etchants, it may be difficult to sufficiently remove the residues.

Patent Literature 1 discloses an etchant that can solve these problems, which is an oxalic acid-based etchant containing a naphthalenesulfonic acid condensate as a surfactant. The recent diversification in device structure has brought about a demand for multi-functionalization of etchants. Etchants are desirable which can be used, without being replaced, to treat any of the following substrates: an ITO film formed on SiN, an ITO film formed on an organic film, and an ITO film formed on a glass substrate, as well as those having combinations of the foregoing embodiments. However, conventional etchants still provide insufficient residue removal, and therefore leave room for improvement.

Moreover, oxalic acid etchants may form precipitates of oxalic acid when moisture is evaporated over time or during use. In the fabrication of electronic components where even particles smaller than 1 μm can cause a problem, such precipitates are a critical problem. For example, the adhesion of such oxalic acid precipitates to a substrate transport system or other systems within manufacturing equipment can cause failure in transportation of substrates, which may result in reduced yield. In addition, the precipitates may clog the filter provided for circulation of the treatment solution, thereby requiring an expensive replacement cost. For this reason, such etchants need to be replaced before precipitates are formed, even though they still sufficiently function as etchants. Consequently, these etchants unfortunately have a short life.

### CITATION LIST

### Patent Literature

Patent Literature 1: WO 2008/32728

### SUMMARY OF INVENTION

### Technical Problem

The present invention aims to provide etchants suitable for etching indium oxide-based films in which precipitation of oxalic acid is reduced even when moisture is evaporated and which provide excellent residue removal not only on organic films and SiN but also on glass. Also, in view of the problem that typical oxalic acid-based etchants allow a solid salt of oxalic acid and indium to precipitate as the etching process proceeds, the present invention aims to provide etchants that have a high solubility of indium to reduce precipitation of a salt of oxalic acid and indium, and therefore can be used for a long period of time. The present invention also aims to provide etchants that maintain a high etching rate.

### Solution to Problem

The present inventor has made various studies to solve the above problems, and found that with a primary amine having two or more hydroxy groups and/or a polyhydric alcohol, precipitation of oxalic acid crystals can be reduced, and residue removal on glass can be greatly improved while maintaining residue removal on organic films and SiN. The finding has led to the completion of the present invention.

Specifically, the present invention relates to an etchant for etching an indium oxide-based film, the etchant containing: (A) oxalic acid; (B) a primary amine having two or more hydroxy groups and/or a polyhydric alcohol; and (C) water.

The primary amine having two or more hydroxy groups and/or polyhydric alcohol (B) are/is preferably present in an amount of 1 to 5 wt %.

The primary amine having two or more hydroxy groups and/or polyhydric alcohol (B) are/is preferably at least one selected from the group consisting of tris(hydroxymethyl)aminomethane, 2-amino-1,3-propanediol, 2-amino-2-methyl-1,3-propanediol, and 2-amino-2-ethyl-1,3-propanediol.

The etchant preferably further contains (D) a naphthalenesulfonic acid condensate and/or polyvinylpyrrolidone.

The oxalic acid (A) and the primary amine having two or more hydroxy groups and/or polyhydric alcohol (B) are preferably present at a ratio by weight of 100:25 to 25:100.

The etchant preferably further contains (E) an inorganic acid.

### Advantageous Effects of Invention

The etchant of the present invention contains oxalic acid, and a primary amine having two or more hydroxy groups and/or a polyhydric alcohol in order to reduce precipitation of oxalic acid during moisture evaporation and to provide excellent residue removal not only on organic films and SiN but also on glass. Therefore, the etchant of the present invention is suitable for etching indium oxide-based films.

### DESCRIPTION OF EMBODIMENTS

The etchant of the present invention contains: (A) oxalic acid; (B) a primary amine having two or more hydroxy groups and/or a polyhydric alcohol; and (C) water, and is used for etching an indium oxide-based film.

The oxalic acid (A) functions as an etching agent for indium oxide in the etchant of the present invention. Examples of the oxalic acid (A) include not only oxalic acid itself but also alkali salts of oxalic acid. The amount of the oxalic acid (A) is preferably, but not limited to, 0.5 to 15 wt %, more preferably 1 to 7 wt % of the etchant. An amount of the oxalic acid (A) less than 0.5 wt % may lead to an insufficient etching rate, while an amount more than 15 wt % may exceed the soluble amount, causing precipitation.

The primary amine having two or more hydroxy groups and polyhydric alcohol (B) are not limited as long as they have two or more hydroxy groups.

Examples of the primary amine having two or more hydroxy groups include tris(hydroxymethyl)aminomethane, 2-amino-1,3-propanediol, 2-amino-2-methyl-1,3-propanediol, 2-amino-2-ethyl-1,3-propanediol, tris(hydroxymethyl)aminomethane, and glucosamine. Examples of the polyhydric alcohol include ethylene glycol, propylene glycol, diethylene glycol, triethylene glycol, glycerol, polyvinyl alcohol, and pentaerythritol. For reduction in precipitation of a salt of oxalic acid and indium, at least one selected from the group consisting of tris(hydroxymethyl)aminomethane, 2-amino-1,3-propanediol, 2-amino-2-methyl-1,3-propanediol, and 2-amino-2-ethyl-1,3-propanediol is preferred. These primary amines and polyhydric alcohols may be used in combination.

The amount of the primary amine having two or more hydroxy groups and/or polyhydric alcohol (B) is preferably, but not limited to, 1 to 5 wt %, more preferably 2 to 4 wt % of the etchant. An amount less than 1 wt % may not be sufficiently effective in reducing precipitation of oxalic acid during moisture evaporation. An amount more than 5 wt % may lead to a lower etching rate.

In the case where the etchant contains a combination of a primary amine having two or more hydroxy groups and a polyhydric alcohol, the ratio of the primary amine having two or more hydroxy groups to the polyhydric alcohol [(primary amine having two or more hydroxy groups):polyhydric alcohol] is preferably, but not limited to, 100:25 to 25:100 by weight.

The amount of the water (C) is the balance obtained by subtracting the amounts of the components contained in the etchant. The amount of the water (C) is preferably, for example, 60 to 99.5 wt %, more preferably 90 to 99.5 wt %.

The etchant of the present invention may contain other components in addition to the above-described components. Non-limiting examples of other components include amines other than primary amines having two or more hydroxy groups, alcohols other than polyhydric alcohols, alkali components, acid components, antifoaming agents, surfactants, anticorrosives, and organic solvents. These components may be used alone or in combination.

Examples of the amines other than primary amines having two or more hydroxy groups include methyl diethanolamine. In the case where the etchant contains methyl diethanolamine, the ratio of methyl diethanolamine to the primary amine having two or more hydroxy groups and/or polyhydric alcohol (B) [methyl diethanolamine:(primary amine having two or more hydroxy groups and/or polyhydric alcohol (B))] is preferably, but not limited to, 100:25 to 25:100 by weight. When the ratio is out of the range indicated above, the combined use of these components may be less effective in reducing precipitation of a salt of oxalic acid and indium.

Besides methyl diethanolamine, examples of the amines other than primary amines having two or more hydroxy groups include monoethanolamine and diethanolamine. Examples of the alcohols other than polyhydric alcohols include ethanol, isopropanol, and diethylene glycol monomethyl ether. The amines other than primary amines having two or more hydroxy groups and/or the alcohols other than polyhydric alcohols may be used alone or in combination. In the case where they are used in combination, examples of the combination include a combination of methyl diethanolamine and ethanol, a combination of methyl diethanolamine and isopropanol, a combination of methyl diethanolamine and monoethanolamine, and a combination of methyl diethanolamine and diethanolamine.

The ratio of the amines other than primary amines having two or more hydroxy groups and/or the alcohols other than polyhydric alcohols to the primary amine having two or more hydroxy groups and/or polyhydric alcohol (B) [(amines other than primary amines having two or more hydroxy groups and/or alcohols other than polyhydric alcohols):(primary amine having two or more hydroxy groups and/or polyhydric alcohol (B))] is preferably, but not limited to, 100:25 to 25:100 by weight.

Any known surfactant may be used. Yet, for improvement of residue removal, the etchant preferably contains (D) a naphthalenesulfonic acid condensate and/or polyvinylpyrrolidone. These surfactants may be used in combination with any other surfactant.

The naphthalenesulfonic acid condensate may be a condensate of β-naphthalenesulfonic acid or a salt thereof with formaldehyde or other compounds. Examples of the salt of β-naphthalenesulfonic acid include, without limitation, sodium salts, potassium salts, ammonium salts, monoethanolamine salts, and triethanolamine salts. The molecular weight of the naphthalenesulfonic acid condensate is preferably, but not limited to, 1000 to 5000. Commercially available products that can be used as the naphthalenesulfonic acid condensate include, for example, LAVELIN FM-P, LAVELIN FH-P (both available from DKS Co. Ltd.), MX-2045L (available from Kao Corporation), and POLITY N-100K (available from Lion corporation). These products may be used alone or in combination.

The amount of the naphthalenesulfonic acid condensate is preferably, but not limited to, 0.005 to 5 wt %, more preferably 0.01 to 1 wt %. An amount of the naphthalenesulfonic acid condensate less than 0.005 wt % may lead to insufficient residue removal, while an amount more than 5 wt % may lead to insufficiently improved residue removal and a lower etching rate.

The amount of polyvinylpyrrolidone is preferably, but not limited to, 0.005 to 2 wt %, more preferably 0.01 to 1 wt %, still more preferably 0.05 to 0.5 wt %. An amount of polyvinylpyrrolidone less than 0.005 wt % may lead to insufficient residue removal, while an amount more than 2 wt % may lead to an increased viscosity.

The polyvinylpyrrolidone may have any K value, but preferably has a K value of 10 to 60. A K value less than 10 or more than 60 may lead to insufficient residue removal. The term “K value” as used herein refers to a viscosity characteristic value that correlates with molecular weight.

In the case where the etchant contains a combination of polyvinylpyrrolidone and a naphthalenesulfonic acid condensate, the ratio of polyvinylpyrrolidone to the naphthalenesulfonic acid condensate (polyvinylpyrrolidone:naphthalenesulfonic acid condensate) is preferably, but not limited to, 100:1 to 0.5:100 by weight. When the ratio is out of the range indicated above, the combined use of both components may be less effective in improving residue removal.

Examples of the acid components include inorganic acids (E) such as hydrochloric acid and sulfuric acid.

The amount of the inorganic acid (E) is preferably, but not limited to, 0.01 to 0.3 wt %, more preferably 0.01 to 0.2 wt %. An amount less than 0.01 wt % may be less effective in reducing precipitation of a salt of oxalic acid and indium, while an amount more than 0.3 wt % may lead to a lower etching rate.

Examples of the antifoaming agents include, without limitation, lower alcohols and polyoxyalkylene alkyl ethers.

These antifoaming agents may be used alone or in combination.

The etchant of the present invention may be prepared by mixing (with stirring at room temperature) the components described above by an ordinary method.

The etchant of the present invention may be used to etch an indium oxide-based film formed on a substrate (e.g. glass) by sputtering or other techniques, thereby enabling patterning. The etchant of the present invention is also suitable for etching an indium oxide-based film formed on an undercoat film formed on a substrate. Examples of the indium oxide-based film include, without limitation, indium tin oxide (ITO) films, indium zinc oxide (IZO) films, and indium gallium zinc oxide (IGZO) films. The term “undercoat film” as used herein refers to a film which is formed on a substrate prior to the formation of an indium oxide-based film and on which the indium oxide-based film is formed. Examples of the undercoat film include, without limitation, silicon nitride (SiN) films and organic films. SiN films are used, for example, to prevent contamination of metallic impurities from the glass substrate, while organic films are used, for example, to flatten the aperture region and improve the aperture ratio.

The etchant of the present invention may be used at room temperature or with heating, e.g. at 25° C. to 50° C. The etching duration required varies depending on the thickness of the indium oxide-based film and other factors, but is typically about 1 to 30 minutes, for example. The etched substrate may be washed in a rinsing step, as needed.

The etchant of the present invention may be brought into contact with the indium oxide-based film by any method, such as by showering, immersion, immersion with shaking, or US immersion.

In an exemplary application where the etchant of the present invention may be used, a substrate made of a material such as a semiconductor, glass, or resin, an undercoat film, an indium oxide-based film, and a resist serving as a mask are stacked in the given order to give a stack, and the resist is patterned and then used as a mask to etch the indium oxide-based film with the etchant of the present invention. This stack may include an insulating film, metal interconnect, TFT, or other components, if necessary, between the substrate and the indium oxide-based film and/or between the indium oxide-based film and the resist. Examples of the metal constituting the metal interconnect include, without limitation, Cu, Al, Mo, Ti, Zr, Mn, Cr, Ca, Mg, and Ni. These metals may be used alone or in combination. The resist may be a known one which may be either a positive or negative resist.

### EXAMPLES

The present invention is described with reference to examples below. The examples, however, are not intended to limit the scope of the present invention. Hereinafter, the terms “part(s)” and “%” refer to “part(s) by weight” and “wt %”, respectively, unless otherwise specified.

### Examples 1 to 21, Comparative Examples 1 to 16

The components shown in the following Table 1 in the respective amounts were mixed to obtain an etchant (total: 100 wt %). The etchants thus prepared were evaluated for drying resistance, etching rate, residue removal, and indium (In) solubility by the methods described below. The results are shown in Table 1.

### (Evaluation Methods)

### 1. Drying Resistance

The etchant (10 g) obtained in each of the examples and comparative examples was weighed into a 50-ml beaker and stored in a 40° C. thermostatic oven for 24 hours. The appearance of the etchants after storage was visually observed and evaluated based on the following criteria.

Good: transparent viscous material
Fair: transparent solid material
Poor: crystal precipitated

### 2. Etching Rate

The sheet resistance of a glass substrate on which an ITO film having a known thickness is formed is measured. The substrate with an ITO film is treated by immersion in the etchant (45° C.) obtained in each of the examples and comparative examples for a period of time until the sheet resistance becomes approximately twice the sheet resistance before the treatment. The thickness of the ITO film after the treatment is calculated from the sheet resistance values before and after the treatment and the initial thickness of the film. The etching rate was calculated from the treatment duration and the change in film thickness and evaluated based on the following criteria.

H: 60 nm/min or higher
L: lower than 60 nm/min

### 3. Residue Removal

### 3-1. On Glass Film

An ITO film was formed on a glass substrate. This substrate was subjected to etching for a period of time that was 1.4 times the just etching time calculated from the etching rate. The etched sample was rinsed with water, blown with nitrogen, and then observed with an electron microscope. The residues after etching were evaluated based on the criteria below.

### 3-2. On Organic Film

An organic film (polyimide film) was formed on a glass substrate, and an ITO film was then formed on the organic film. This substrate was subjected to etching for a period of time that was 1.4 times the just etching time calculated from the etching rate. The etched sample was rinsed with water, blown with nitrogen, and then observed with an electron microscope. The residues after etching were evaluated based on the criteria below.

### 3-3. On Silicon Nitride (SiN) Film

A silicon nitride (SiN) film was formed on a glass substrate, and an ITO film was then formed on the silicon nitride film. This substrate was subjected to etching for a period of time that was 1.4 times the just etching time calculated from the etching rate. The etched sample was rinsed with water, blown with nitrogen, and then observed with an electron microscope. The residues after etching were evaluated based on the following criteria.

Good: very small amount
Fair: small amount
Poor: large amount

### 4. Indium (in) Solubility

An Erlenmeyer flask was charged with the etchant prepared in each of the examples and comparative examples and then with indium oxide. After a reflux condenser was attached to the flask, the mixture was boiled with stirring for four hours. After completion of the boiling, the mixture was cooled at 25° C. for 48 hours. Then, the precipitation of a supersaturated indium compound was confirmed, followed by filtration of the mixture through a filter having a pore size of 0.2 μm. The filtrate was collected, and the indium concentration in the filtrate was measured by ICP optical emission spectrometry. The results were evaluated based on the following criteria.

H: at least 900 ppm
M: at least 300 ppm but less than 900 ppm
L: less than 300 ppm

TABLE 1

| | | Composition (wt. %) | | | | | | | Evaluation results | | | | | |
|---|---|---|---|---|---|---|---|---|---|---|---|---|---|---|
| | | | | | Naphthalene- | | | | | | | | | |
| | | | | | sulfonic | | | | | | | | | |
| | | | | | acid- | | Hydro- | | | | Residue removal | | | In |
| Example | | Oxalic | Amine or alcohol | | formaldehyde | Polyvinyl- | chrolic | | Drying | Etching | | Organic | | solu- |
| No. | | acid | Type | Amount | condensate | pyrrolidone | acid | Water | resistance | rate | Glass | film | SiN | bility |
| Exam- | 1 | 3 | Tris(hydroxy- | 1 | 0.5 | | | Balance | Fair | H | Good | Good | Fair | M |
| ple | | | methyl) | | | | | | | | | | | |
| | | | amino- | | | | | | | | | | | |
| | | | methane | | | | | | | | | | | |
| | 2 | 3 | Tris(hydroxy- | 1 | 0.5 | 0.5 | 0.2 | Balance | Fair | H | Good | Good | Good | M |
| | | | methyl) | | | | | | | | | | | |
| | | | amino- | | | | | | | | | | | |
| | | | methane | | | | | | | | | | | |
| | 3 | 3 | 2-Amino-1,3- | 2 | 0.5 | | | Balance | Good | H | Good | Good | Fair | M |
| | | | propanediol | | | | | | | | | | | |
| | 4 | 3 | 2-Amino-1,3- | 2 | | 0.5 | | Balance | Good | H | Good | Good | Fair | M |
| | | | propanediol | | | | | | | | | | | |
| | 5 | 3 | 2-Amino-1,3- | 2 | 0.5 | 0.5 | | Balance | Good | H | Good | Good | Good | M |
| | | | propanediol | | | | | | | | | | | |
| | 6 | 3 | 2-Amino-1,3- | 2 | 0.5 | 0.5 | 0.2 | Balance | Good | H | Good | Good | Good | H |
| | | | propanediol | | | | | | | | | | | |
| | 7 | 3 | 2-Amino-1,3- | 5 | 0.5 | 0.5 | | Balance | Good | H | Good | Good | Good | H |
| | | | propanediol | | | | | | | | | | | |
| | 8 | 3 | 2-Amino-1,3- | 5 | 0.5 | | | Balance | Fair | L | Good | Good | Fair | H |
| | | | propanediol | | | | | | | | | | | |
| | 9 | 3 | 2-Amino-2- | 2 | 0.5 | | | Balance | Good | H | Good | Good | Fair | M |
| | | | methyl- | | | | | | | | | | | |
| | | | 1,3- | | | | | | | | | | | |
| | | | propanediol | | | | | | | | | | | |
| | 10 | 3 | 2-Amino-2- | 2 | 0.5 | | | Balance | Good | H | Good | Good | Fair | M |
| | | | ethyl- | | | | | | | | | | | |
| | | | 1,3- | | | | | | | | | | | |
| | | | propanediol | | | | | | | | | | | |
| | 11 | 3 | Tris(hydroxy- | 2 | 0.5 | | | Balance | Good | H | Good | Good | Fair | M |
| | | | methyl) | | | | | | | | | | | |
| | | | amino- | | | | | | | | | | | |
| | | | methane | | | | | | | | | | | |
| | 12 | 3 | Ethylene | 2 | 0.5 | | | Balance | Good | H | Fair | Good | Fair | L |
| | | | glycol | | | | | | | | | | | |
| | 13 | 3 | Propylene | 2 | 0.5 | | | Balance | Good | H | Fair | Good | Fair | L |
| | | | glycol | | | | | | | | | | | |
| | 14 | 3 | Diethylene | 2 | 0.5 | | | Balance | Good | H | Fair | Good | Fair | L |
| | | | glycol | | | | | | | | | | | |
| | 15 | 3 | Triethylene | 2 | 0.5 | | | Balance | Good | H | Fair | Good | Fair | L |
| | | | glycol | | | | | | | | | | | |
| | 16 | 3 | Glycerol | 2 | 0.5 | | | Balance | Good | H | Fair | Good | Fair | L |
| | 17 | 3 | Glycerol | 5 | 0.5 | | | Balance | Good | L | Fair | Good | Fair | L |
| | 18 | 3 | Polyvinyl | 2 | 0.5 | | | Balance | Good | H | Fair | Good | Fair | L |
| | | | alcohol | | | | | | | | | | | |
| | | | (degree of | | | | | | | | | | | |
| | | | poly- | | | | | | | | | | | |
| | | | merization = | | | | | | | | | | | |
| | | | 500) | | | | | | | | | | | |
| | 19 | 3 | Tris(hydroxy- | 1 | 0.5 | | | Balance | Good | H | Fair | Good | Fair | M |
| | | | methyl) | | | | | | | | | | | |
| | | | amino- | | | | | | | | | | | |
| | | | methane | | | | | | | | | | | |
| | | | Propylene | 1 | | | | | | | | | | |
| | | | glycol | | | | | | | | | | | |
| | 20 | 3 | Tris | 1.5 | 0.5 | | | Balance | Good | H | Fair | Good | Fair | H |
| | | | (hydroxy- | | | | | | | | | | | |
| | | | methyl) | | | | | | | | | | | |
| | | | amino- | | | | | | | | | | | |
| | | | methane | | | | | | | | | | | |
| | | | Methyl | 1 | | | | | | | | | | |
| | | | diethano- | | | | | | | | | | | |
| | | | lamine | | | | | | | | | | | |
| | 21 | 3 | 2-Amino-2- | 1.5 | 0.5 | | | Balance | Good | H | Fair | Good | Fair | H |
| | | | ethyl- | | | | | | | | | | | |
| | | | 1,3- | | | | | | | | | | | |
| | | | propanediol | | | | | | | | | | | |
| | | | Methyl | 1 | | | | | | | | | | |
| | | | dielhanol- | | | | | | | | | | | |
| | | | amine | | | | | | | | | | | |
| Com- | 1 | 3 | | | 0.5 | | 0.2 | Balance | Poor | H | Good | Good | Fair | L |
| parative | 2 | 3 | | | | 0.5 | 0.2 | Balance | Poor | H | Good | Good | Fair | L |
| Exam- | 3 | 3 | Mono- | 2 | 0.5 | | | Balance | Poor | H | Good | Good | Fair | H |
| ple | | | ethanol- | | | | | | | | | | | |
| | | | amine | | | | | | | | | | | |
| | 4 | 3 | Mono- | 5 | 0.5 | | | Balance | Poor | L | Fair | Good | Fair | H |
| | | | ethanol- | | | | | | | | | | | |
| | | | amine | | | | | | | | | | | |
| | 5 | 3 | Diglycol- | 1 | 0.5 | | | Balance | Poor | H | Poor | Good | Fair | M |
| | | | amine | | | | | | | | | | | |
| | 6 | 3 | Methyl | 1 | 0.5 | 0.5 | 0.2 | Balance | Fair | H | Poor | Good | Good | M |
| | | | diethanol- | | | | | | | | | | | |
| | | | amine | | | | | | | | | | | |
| | 7 | 3 | Diethanol- | 1 | 0.5 | | | Balance | Poor | H | Poor | Good | Fair | M |
| | | | amine | | | | | | | | | | | |
| | 8 | 3 | Ethanol | 2 | 0.5 | | | Balance | Poor | H | Fair | Good | Fair | L |
| | 9 | 3 | Isopropanol | 2 | 0.5 | | | Balance | Poor | H | Fair | Good | Fair | L |
| | 10 | 3 | diethylene | 2 | 0.5 | | | Balance | Poor | H | Fair | Good | Fair | L |
| | | | glycol | | | | | | | | | | | |
| | | | monomethyl | | | | | | | | | | | |
| | | | ether | | | | | | | | | | | |
| | 11 | 3 | Dimethyl | 2 | 0.5 | | | Balance | Poor | H | Fair | Good | Fair | L |
| | | | sulfoxide | | | | | | | | | | | |
| | 12 | 3 | Diglycol- | 2 | 0.5 | | | Balance | Good | H | Poor | Good | Fair | M |
| | | | amine | | | | | | | | | | | |
| | 13 | 3 | Diglycol- | 2 | 0.5 | | 0.2 | Balance | Good | H | Poor | Good | Fair | M |
| | | | amine | | | | | | | | | | | |
| | 14 | 3 | Methyl | 2 | 0.5 | | | Balance | Good | H | Poor | Good | Fair | M |
| | | | diethanol- | | | | | | | | | | | |
| | | | amine | | | | | | | | | | | |
| | 15 | 3 | Tetramethyl- | 2 | 0.5 | | | Balance | Good | H | Poor | Good | Fair | M |
| | | | ammonium | | | | | | | | | | | |
| | | | hydroxide | | | | | | | | | | | |
| | 16 | 3 | Diethanol- | 2 | 0.5 | | | Balance | Good | H | Poor | Good | Fair | M |
| | | | amine | | | | | | | | | | | |

The results in Table 1 show that the etchants containing a primary amine having only one hydroxy group as in Comparative Examples 3 to 5, 12, and 13 are inferior in drying resistance or residue removal on glass. The etchants containing a secondary or tertiary amine having two or more hydroxy groups as in Comparative Examples 6, 7, 14, and 16 are inferior in residue removal on glass. The etchants containing an alcohol having only one hydroxy group or dimethyl sulfoxide as in Comparative Examples 8 to 11 are inferior in drying resistance and indium solubility. In contrast, the etchants containing a primary amine having two or more hydroxy groups and/or a polyhydric alcohol as in Examples 1 to 21 are superior in drying resistance and residue removal on SiN, organic film, and glass.

### INDUSTRIAL APPLICABILITY

In the etchant of the present invention, the precipitation of oxalic acid due to moisture evaporation is reduced. The etchant of the present invention also provides excellent residue removal not only on organic films and SiN but also on glass. Therefore, the etchant of the present invention is suitable for etching indium oxide-based films.

1. An etchant for etching an indium oxide-based film, the etchant comprising:
(A) oxalic acid;
(B) a primary amine having two or more hydroxy groups and/or a polyhydric alcohol; and
(C) water.

2. The etchant according to claim 1,
wherein the primary amine having two or more hydroxy groups and/or polyhydric alcohol (B) are/is present in an amount of 1 to 5 wt %.

3. The etchant according to claim 1,
wherein the primary amine having two or more hydroxy groups and/or polyhydric alcohol (B) are/is at least one selected from the group consisting of tris(hydroxymethyl)aminomethane, 2-amino-1,3-propanediol, 2-amino-2-methyl-1,3-propanediol, and 2-amino-2-ethyl-1,3-propanediol.

4. The etchant according to claim 1, further comprising (D) a naphthalenesulfonic acid condensate and/or polyvinylpyrrolidone.

5. The etchant according to claim 1,
wherein the oxalic acid (A) and the primary amine having two or more hydroxy groups and/or polyhydric alcohol (B) are present at a ratio by weight of 100:25 to 25:100.

6. The etchant according to claim 1, further comprising (E) an inorganic acid.
